(19) United States
(12) Patent Application Publication
(10) Pub. No.: US 2013/0045560 A1
(43) Pub. Date: Feb. 21, 2013

(54) TECHNIQUES AND SYSTEMS FOR FABRICATING ANTI-REFLECTIVE AND PASSIVATION LAYERS ON SOLAR CELLS

(71) Applicants: Graham T. MacWilliams, Los Altos Hills, CA (US); Duncan S. MacWilliams, Los Altos Hills, CA (US); Kenneth P. MacWilliams, Los Altos Hills, CA (US)

(72) Inventors: Graham T. MacWilliams, Los Altos Hills, CA (US); Duncan S. MacWilliams, Los Altos Hills, CA (US); Kenneth P. MacWilliams, Los Altos Hills, CA (US)

(73) Assignee: Kenneth P. MacWilliams

(21) Appl. No.: 13/211,272

(22) Filed: Aug. 16, 2011

(51) Int. Cl. H01L 31/18; B05C 11/00

(52) U.S. Cl. 438/65; 118/695; 257/E31.117

(57) ABSTRACT

The present invention is directed to techniques for fabricating solar cells that feature annealing of a substrate and subsequent formation of a combination passivation and antireflective layer in superimposition with a p-n junction formed on the substrate by introductions of impurities. It was determined that the time and cost for manufacture may be reduced by annealing the substrate before formation of the combination layer and maintaining the temperature proximate to the annealing temperature. To that end, upon completion of the anneal process the temperature of the substrate is maintained within an acceptable temperature range to reduce the time required for the substrate to reach temperature for formation of the combination layer. The combination layer is then formed without undue delay using plasma deposition processes.

The present invention relates to photovoltaic cells and more particularly to the manufacturing of photovoltaic cells having anti-reflective coating disposed thereon.

A photovoltaic cell, or solar cell, is a transducer for converting optical energy into electrical energy. It consists of a photodiode that is zero biased. Upon being exposed to photons, electrical current is produced and restricted from flowing so that voltage builds. This enables solar cells to generate electricity to power equipment and/or recharge a battery. Solar cells are used in over 100 countries to produce vast quantities of electricity and are one of the faster growing markets of power-generation today. This has resulted from continued improvement in the power generation capabilities of solar cells.

FIG. 1 shows a basic configuration of a solar cell as described in U.S. Pat. No. 3,091,555 to Smythe. The solar cell includes a semiconductor substrate 10 formed of n-type material. A layer 12 of p-type material is formed by a solid state diffusing a suitable P-type impurity into the n-type material using conventional techniques. An oxide coating 13 of silicon is formed on layer 12. Coating 13 reduces the number of photons reflected from the p-layer compared to the number of photons that would be reflected in the absence thereof. In a preferred embodiment of the present invention, coating 13 is fabricated from silicon nitride, SiON, AlO, or silicon dioxide or any combination of such layers. Solar energy impinging upon semiconductor substrate 10 interacts with the material of semiconductor substrate 10 forming electron-hole pairs. This causes a voltage to appear between terminals 15 and 16. The voltage may be applied across a suitable load 17 to cause current to flow therethrough. Improved efficiency of the solar cell is attributed to the low reflectance coating 13 that reduces, if not prevents, large quantities of solar energy from reflecting away from layer 12.

U.S. Pat. No. 4,086,102 to King discloses an inexpensive solar and method therefore that includes a single protective layer that functions as an anti-reflection coating and an encapsulation. In cases where the junction is formed by ion implantation techniques, the same layer also serves as the implantation oxide. In addition, this multi-purpose layer may also serve as a mass analyzer, allowing the desired species of ions to reach the surface of the semiconductor but blocking the heavier undesired species. The necessary contacts may be formed prior to implantation, and the use of alloyed aluminum contacts with aluminum oxide passivation permits a simplified contacting procedure.

U.S. Pat. No. 4,818,337 to Barnett et al. discloses high efficiency, thin active-layer silicon solar cells and a process for their fabrications. The cells are characterized by a capability of employing a low-cost, metallurgical grade silicon for the substrate. The substrate has a silicon dioxide barrier coating with electrical conductivity to the active semiconductor layers provided by a multiplicity of fine holes through the oxide. The holes have silicon therein to afford electrical continuity between the active layers and the silicon of the substrate. The process comprises in situ formation of silicon dioxide on the silicon, formation of the holes in the oxide by photolithography, and etching enabling nucleation and growth of silicon in the holes by epitaxy.

There is a need, however, to improve the manufacturing process of solar cells to reduce the cost per unit.

### BRIEF SUMMARY OF THE INVENTION

The present invention is directed to techniques for fabricating solar cells that feature annealing of a substrate and subsequent formation of a combination passivation and antireflective layer in superimposition with a p-n junction. It was determined that the time for manufacture may be reduced by annealing the substrate to a temperature before formation of the combination passivation and antireflective layer and maintaining the temperature to be a close to the anneal temperatures as possible. To that end, upon completion of the anneal process the temperature of the substrate is maintained within an acceptable temperature range to reduce the time required for the substrate to reach temperature for formation of the combination layer. The combination layer is then formed without undue delay using plasma deposition processes. One embodiment is directed to the method of fabricating a solar cell containing implanted ions of a impurity element of a given conductivity type into a semiconductive substrate of an opposite conductivity type to produce p-n junction therein and heating the substrate to anneal the substrate and forming, following the anneal, a layer of combined antireflective and protective material in superimposition with the p-n junction. Another embodiment of the method includes disposing into a thermal processing apparatus a semiconductor substrate of a first conductivity type having a p-n junction formed therein by the presence of ions of a second conductivity type implanted therein; applying heat to anneal the substrate with the thermal processing apparatus; transferring the substrate from the thermal processing apparatus to a plasma deposition chamber white maintaining the temperature to be within a range of temperatures; and forming a layer of combined antireflective and protective material in superimposition with the p-n junction by exposing the semiconductor substrate to plasma chemistries. Also disclosed are various processing systems to carry-out the claimed methods.

### BRIEF DESCRIPTION OF THE DRAWINGS

FIG. 1 is a side view of a solar cell in accordance with the prior art;

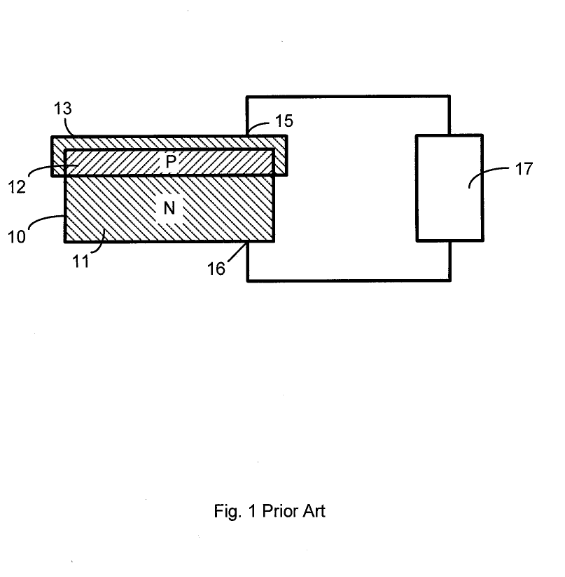

FIG. 2 is a side view of a solar cell fabricated in accordance with the present invention;

FIG. 3 is a simplified plan view of a processing system for fabricating a solar cell in accordance with a first embodiment of the present invention;

FIG. 4 is a side view of a layer stack upon which an antireflective layer is deposited with the system shown in FIG. 3 to fabricate the solar cell shown in FIG. 2;

FIG. 5 is a side view of the layer stack shown in FIG. 4 with an antireflective layer deposited thereon;

FIG. 6 is a flow diagram showing the steps of fabricating the solar cell shown in FIG. 2;

FIG. 7 is a simplified plan view of a processing system for fabricating a solar cell in accordance with a second embodiment of the present invention while carrying-out the steps shown in FIG. 6; and

FIG. 8 is a simplified side view of a processing system for fabricating a solar cell in accordance with a second embodiment of the present invention while carrying-out the steps shown in FIG. 6.

### DETAILED DESCRIPTION OF THE INVENTION

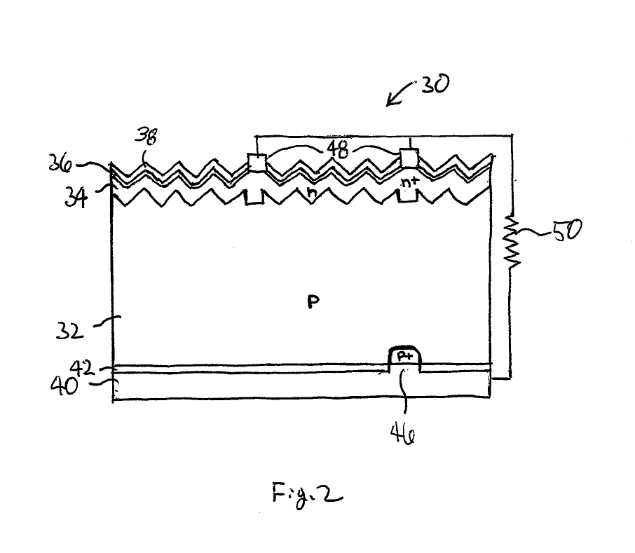

Referring to FIG. 2 an example of a solar cell 30 that may be fabricated in accordance with the present invention is described. Solar cell 30 includes photovoltaically inactive substrate 32 that may be formed from a variety of materials, such as silicon, gallium arsenide and germanium, just to name a few. Substrate 32 may have a wide range of resistivity and doped with either n-type or p-type impurities. In the current example, substrate 32 is doped with p-type impurities. A surface of substrate 32 is typically etched or ‘textured’ to provide a saw-tooth pattern or an optically diffuse surface, and an n-type layer 34 is formed upon a surface of substrate 32 and conforms to the shape thereof and defines a p-n junction at the interface thereof. The p-n junction is formed on the substrate through introduction of impurities, such as by ion implantation, dopant pastes, laser deposition or conventional furnace doping techniques. An oxide layer 36 may be present, although it is optional, which is formed upon n-type layer 34 and conforms to the shape thereof, using standard and well known deposition techniques. Formed upon oxide layer 36, or n-type layer 34 in the absence of oxide layer 36, is a layer that functions as an anti-reflective coating and a protective layer, referred to as AR layer 38. AR layer 38 may be formed from any suitable material. In the present example, AR layer 38 is fabricated from materials selected from a set including silicon nitride and aluminum oxide and is discussed in more detail below. Also formed on a side of substrate 32 opposite to AR layer 38 is a metal layer 40, which in this example is formed from aluminum. Layer 40 is formed using standard techniques. Before formation of layer 40, an optional layer of oxide 42 may be lubricated so as to be located between layer 40 and substrate 32, using standard deposition techniques. Oxide layer 42 may be formed from silicon oxide through passivation of substrate 32, were substrate 32 formed from silicon. Alternatively, oxide layer 42 may be a combination of oxide/nitride grown to form layer 42. At least one of throughway 46 is formed in layer 42 to facilitate electrical communication between metal layer 40 coupling and substrate 32. A plurality of spaced-apart contacts 48 are in electrical communication with n-type layer 34. In this manner, a load 50 may be connected in series between layer 34 and substrate 32.

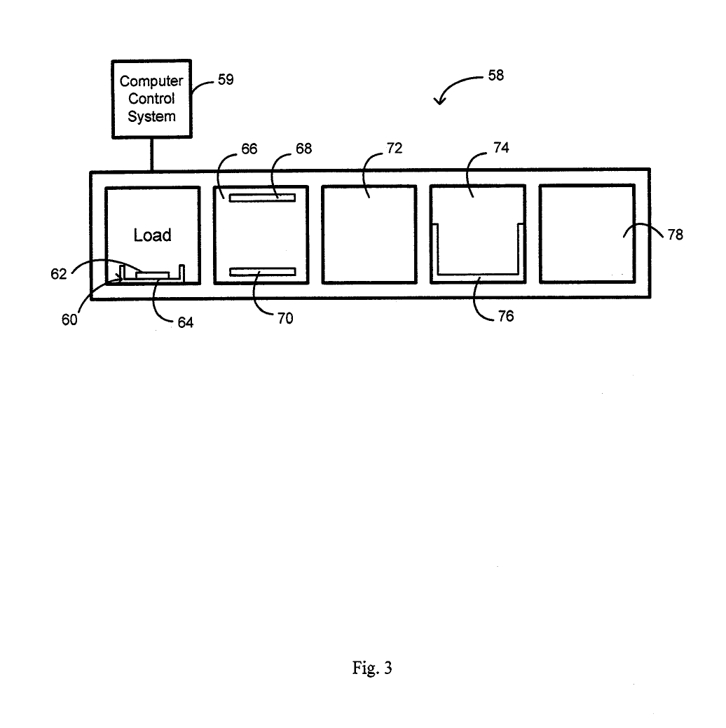

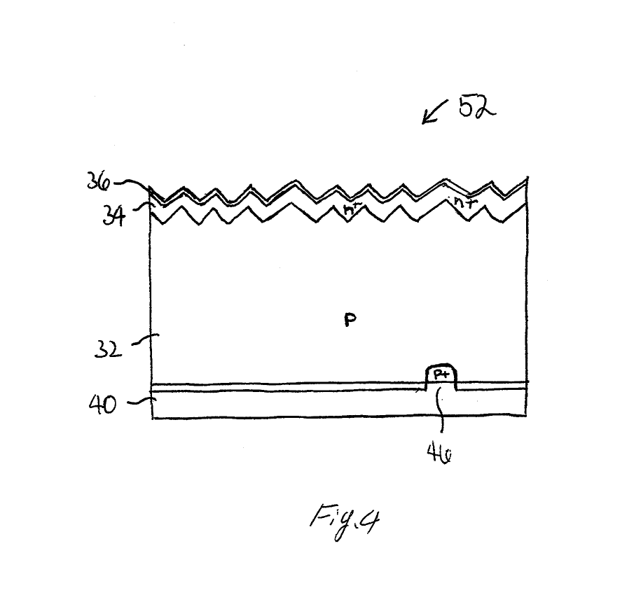

Referring to both FIGS. 3 and 4, the present invention is directed to providing improved techniques for forming AR layer 38. To that end, a system 58 employed in accordance with one embodiment includes sub-system to receive a partially fabricated solar cell 30, referred to as layer stack 52, which includes all of the features discussed above with respect to FIG. 2, excepting that AR layer 38 and contacts 48 are not present. Typically a plurality of layer stacks 52 is formed on a common semiconductor substrate 62 received at a load station 60. Load station 60 may be any known in the art, and it is desired that it can be automated and include a carrier 64 capable of operating at 200° C. or greater and transferring semiconductor substrate 62 between load station 60 and load lock station 66. Load lock station 66 may be any known in the semiconductor processing art capable of heating semiconductor substrate 62 to a desired temperature. For example, load lock station 66 may include a heating system, such as a lamp heating element 68 and/or resistive heating element 70 that may be located so as to be in thermal communication with semiconductor substrate 62. It should be understood that the relative position between semiconductor substrate 62 and either elements 68 and 70 may be any desired, e.g., top, bottom, sides and the like. Carrier 64 also functions to transport semiconductor substrate 62 into processing chamber 72. Processing chamber 72 may be any known in the art capable of depositing layers of silicon dioxide or silicon nitride. In one example, processing chamber 72 is a plasma enhanced chemical vapor deposition (PECVD) chamber. An example of processing chamber 72 is one capable of processing substrates having sides with a length on the order of 0.5 meters to 2 meters long. The deposition parameters to form AR layer 38 from either silicon oxide or silicon nitride are generally well known in the art for semiconductor applications, however have not been well developed for the PV photovoltaic industry. Carrier 64 also operates to transfer semiconductor substrate 62 between processing chamber 72 and post processing toad lock 74. Post processing load lock 74 includes a thermal dissipation subsystem 76 to cool semiconductor substrate 62 to a desired temperature and facilitate unloading the same at unloading station 78. Loading station 60 and unloading station 78 may be substantially identical. Thermal dissipation subsystem 76 may include features to take advantage of any one, or a combination of different thermal dissipation techniques. For example, thermal dissipation subsystem 76 may employ a high thermal conductivity fluid, such as helium, He, gas, or thermal transfer liquid, introduced into cavity of load lock 74. Additionally, the thermal conductivity fluid may move through a conduit, as shown that propagates into and out of load lock 74 whereby thermal energy is transferred to the fluid and out of load lock 74. Although it is not necessary, in one embodiment, the operations of system 58 may occur under control of a processing system 80 having a processor 82 and memory in data communication therewith that stores computer readable data when operated on by processor 82 and has system 58 carry out the functions mentioned above.

Operations of system 58 is under control of a computer control system 59 that is in data communication with each of load station 60, load lock station 66, processing chamber 72, load lock 74 and unloading station 78 and directs the operations thereof. Computer control system 59 may be any known in the computer art and includes a processor (not shown), input and output devices (not shown), and various memory devices (now shown) for storage of computer program code that may be operated on by the processor (now shown) to control the operations of system 58. To that end, Computer code for operating system 58 may be stored on a hard disk (not shown), and the entire program code, or portions thereof may also be stored in any other volatile or non-volatile memory medium or device as is well known, such as a ROM (not shown) or RAM (now shown), or provided on any media capable of storing program code, such as a compact disk (CD) medium, digital versatile disk (DVD) medium, a floppy disk, and the like. It will also be appreciated that computer code for implementing aspects of the present invention can be implemented in any programming language that can be executed on a server or server system such as, for example, in C, Java, or any other scripting language, such as VBScript.

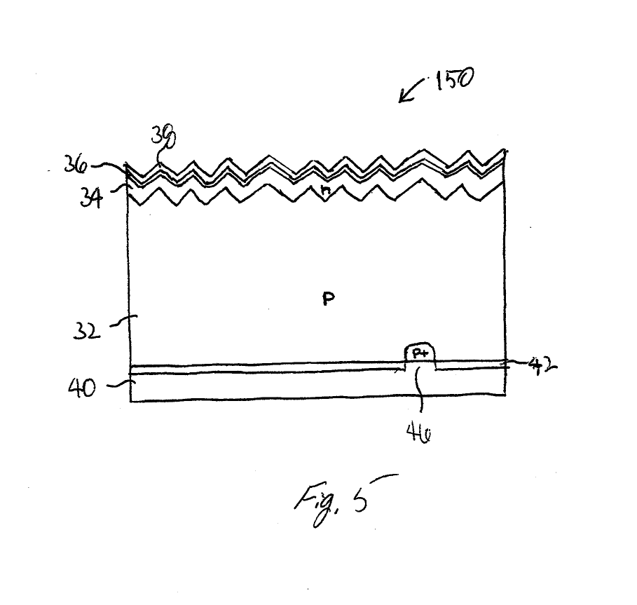

Referring to FIGS. 3 and 5, one advantage of system 58 is that it facilitates rapid formation of AR layer 38. It is desired that toad lock station 66 heating system increases the temperature of semiconductor substrate 62 to anneal semiconductor substrate 62 to a temperature and maintain that temperature as close as possible while semiconductor substrate 62 is transferred to a processing chamber 72 for formation of AR layer 38. To that end, at step 100 semiconductor substrate 62 is heated to a temperature in excess of 400° C. and typically in a range of 800° C. to 1000° C. at load lock station 66. In this manner, the junction dopants are activated in semiconductor substrate 62 and semiconductor substrate 62 is annealed while concurrently heated in preparation for formation of AR layer 38. At step 102, the temperature of semiconductor substrate 62 is maintained at or above the temperature required for anneal of semiconductor substrate 62, and preferably close to the processing temperature for formation of AR layer 38, as carrier 64 introduces semiconductor substrate 62 into processing chamber 72, This temperature of semiconductor substrate 62 upon introduction into process chamber 72 is typically about 400° C. To that end, the rate at which carrier 64 moves between processing chamber 72 and load lock station 66 and the rate of thermal dissipation by the carrier 64 is established to minimize the time required for the processing temperature to form AR layer 38 is reached. The deposition of the silicon oxide, silicon nitride or aluminum oxide is envisioned in this invention to be based on a PECVD technique. However, as mentioned, although basic recipes exist for the deposition of these generic films, much development is underway to optimize the performance and cost of these films for their applications to solar cells. The oxide deposition is typically accomplished with a silane based gas together with an oxidizer (O₂ or N₂O) and typically involves a carrier gas (N₂ or He or Ar) A silicon nitride deposition is typically accomplished with silane gas together with ammonia (NH3) or separate nitrogen (N₂) and Hydrogen (H₂) gases. The silane above that acts as the silicon source could also be provided by non-silane, non-gas alternatives that are emerging in the market. Aluminum oxides (e.g., Al₂O₃) can be deposited using a variety of gases; TMA—TriMethylAluminum is one aluminum source along with an oxygen source (such as O₂ or N₂O) and carrier gas (e.g., N₂, He, Ar). The reactants above are typically deposited in a vacuum chamber pumped to a base pressure below the militorr range to evacuate impurities prior to being re-pressurized with reactants and carrier gas to the process pressure militorr to torr range). The plasma is ignited through the application of RF energy (typically at 13.6 MHZ, sometimes in combination with a lower frequency ˜300 KHZ component) into the chamber at approximately 1W per square centimeter. It is recommended that a direct (vs. indirect) plasma be employed to afford the maximum control of the deposition. After deposition, can be on the order of minutes, the RF energy and plasma is turned off, the chamber is pumped free of reactants and backfilled to initiate cooling and a matching pressure to enable transfer to the coot-down load lock. At step 104, semiconductor substrate 62 is exposed to PECND deposition chemistries to form AR layer 38. Following formation of AR layer 38, layer stack 150 is formed, shown in FIG. 5.

Referring to FIGS. 3, 5 and 6, at step 106, carrier 64 transports one or more semiconductor substrates 62 to load lock station 74. In one example, carrier 64 may transport up to 100 or more semiconductor substrates 62. At step 108, one semiconductor substrate 62 is transferred to unload station 78 by carrier 64. Wafer 64 is unloaded from system 58 and transferred with AR layer 38 for formation of contacts 48, at step 110. During step 110 layer stack 150 is exposed to post AR layer 38 fabrication processes to pattern the same and deposit contacts 48 using well known techniques. For example, were oxide layer 42 formed, processing chamber 72 may be used to fabricate the same so as to include a SiO₂/SiN stack, or Al₂O₃, or SiO₂, or F—SiO₂. Following formation of oxide layer 42 contact holes 46 is fabricated employing conventional techniques, such as lithographic masking and etch techniques, or screen print etch gels, or directed lasers and the like. Metallization 40 is deposited employing using conventional screen print methods, evaporation or sputter deposition. Metal layer 40 may be fabricated from one or more layers of metal to optimize electrical properties of the same.

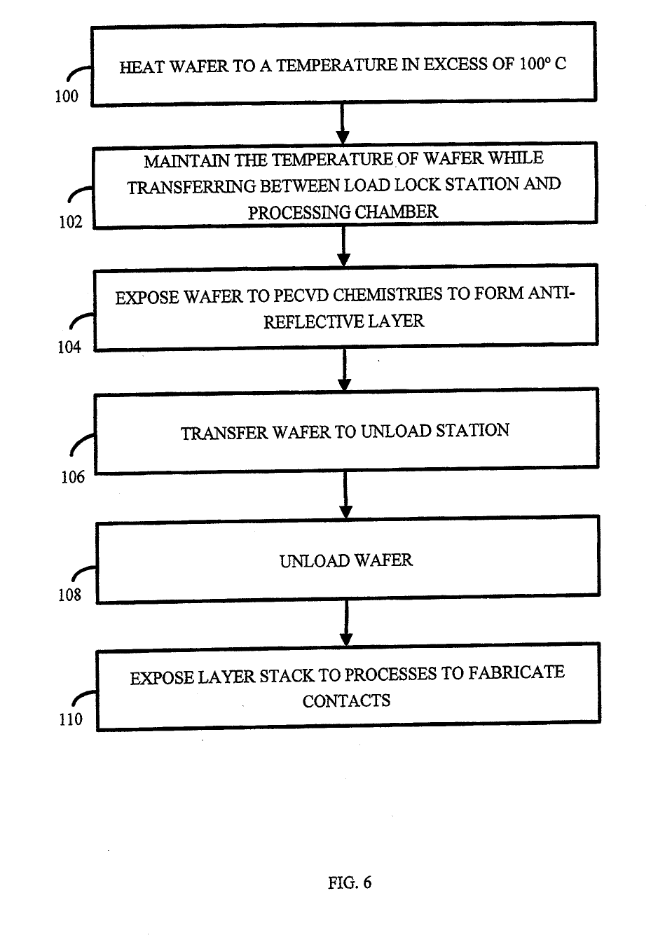

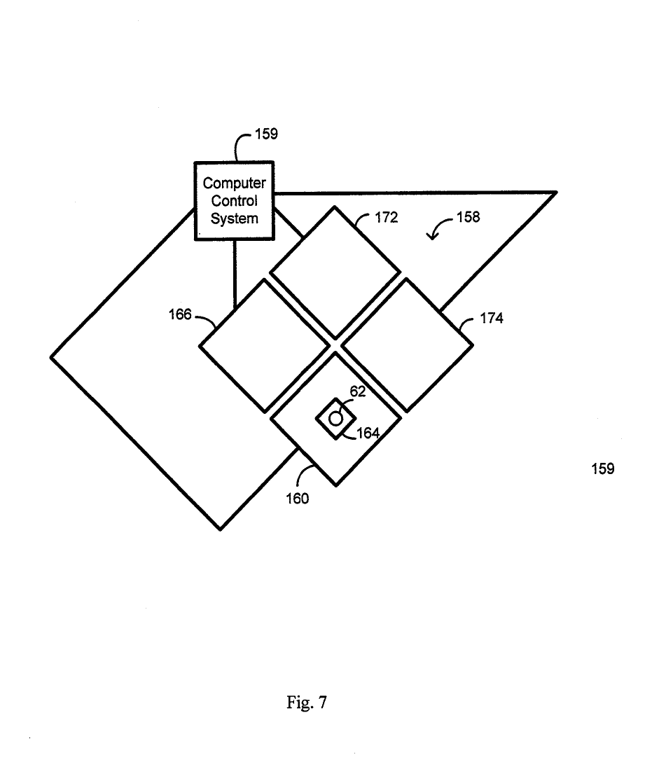

Referring to both FIGS. 3 and 7, in accordance with another embodiment, system 58 may be simplified by omitting one of load station 60 and unload station 78 forming system 158. System 158 includes load/unload station 160, load lock station 166, a processing chamber 172 and a thermal dissipation system 174, which are identical to load lock station 66, a processing chamber 72 and a thermal dissipation system 74. As a result, a carrier 164 is included to transport semiconductor substrate 62 or plurality of wafers among load lock and heat station 166, a processing chamber 172 and a thermal dissipation system 174. However, system 158 includes a single toad/unload station 160 that performs the functions of toad station 60 and unload station 78. A computer control system 159 is employed to control the operations of system 158 in a manner similar to how computer control system 59 regulates the operations of system 58. To use a single load/unload station 160 system 158 has a diamond configuration and simplifies the cost and expense of performing the method discussed with respect to FIG. 6.

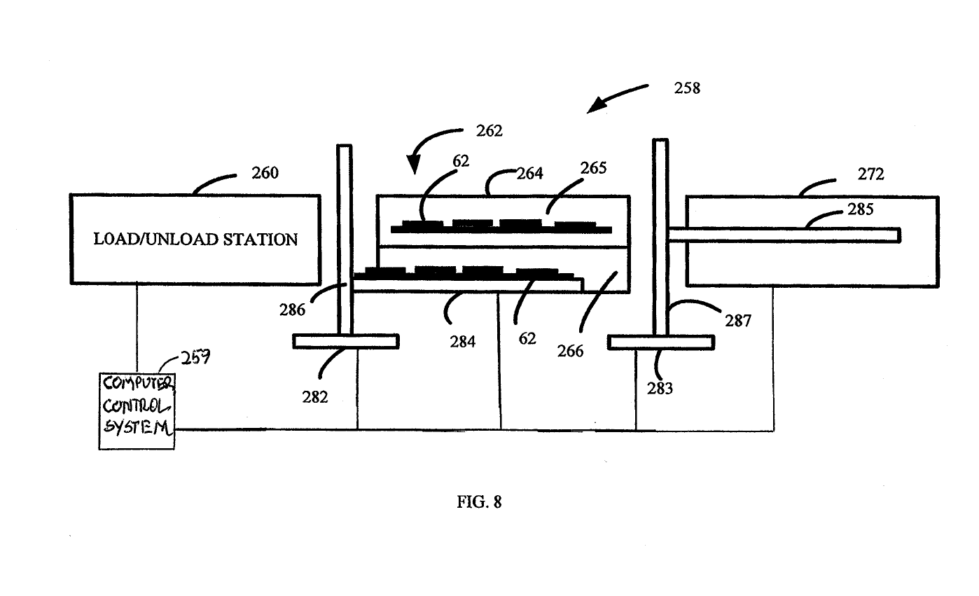

Referring to FIGS. 7 and 8, in accordance with another embodiment, system 158 may be simplified further by combining heated load lock station 166 with thermal dissipation station 174. That that end, system 258 includes a load/unload station 260 that is the same as load/unload 160. A combined heating/thermal dissipation system 262 that carries out the functions of heated toad lock station 166 and thermal dissipation station 174 in included. Heating/thermal dissipation system 262 includes a bifurcated chamber 264 that includes first and second transfer regions 265 and 266. One of transfer regions, 265 for example, is used to facilitate movement of semiconductor substrate 62 between toad/unload station 260 and heating/thermal dissipation system 262. The remaining transfer region 266 facilitates transfer of semiconductor substrates 62 between heating/thermal dissipation system 262 and processing chamber 272. Processing chamber 272 is identical to processing chamber 172. To facilitate movement of semiconductor substrates 62 in two transverse directions 280 and 281 a pair of robots are included in system 258, shown as 282 and 283. Each of robots 282 and 283 includes a transport arm 284 and 285, respectively, which allows movement of semiconductor substrates 62 along direction 280. An elevating shaft 286 and 287 is included in each of robot 282 and 283, respectively, Elevating shaft 286 allows movement of transport arm 284 along direction 281, and elevating shaft 287 allows movement of transport arm 285 along direction 281. In the present example, transfer arms 284 would place semiconductor substrates 62 into transfer region 266 and remove semiconductor substrates 62 from transfer region 265, Conversely, transfer arm 285 would remove substrate from transfer region 266 and insert substrate into transfer region 265. One advantage provided by bifurcated chamber 264 is that by transferring substrates 62 in close proximity facilitates thermal transfer therebetween. As would be appreciated, semiconductor substrates 62 are heated in transfer chamber 265 potentially up to a relative high temperature, e.g., approximately 800° C. and 1000° C. Semiconductor substrates 62 in transfer region 266 are typically cooled to below 200° C. Optimizing the thermals communication between transfer regions 265 and 266 facilitates heating semiconductor substrates 62 in transfer region 266 and cooling of substrate in transfer region 265, thereby increasing the efficiency of system 258. A computer control system 259 is employed to control the operations of system 258 in a manner similar to how computer control system 159 regulates the operations of system 158.

It should be understood that the foregoing description is merely an example of the invention and that modifications may be made thereto without departing from the spirit and scope of the invention and should not be construed as limiting the scope of the invention. For example, which the substrate has been discussed with respect to being formed from a homogenous material, it is possible that the substrate be formed from composition materials. For example, the substrate may be formed from silicon with a layer of gallium-arsenide disposed on top and provided with the requisite impurities to provide a desire resistivity. Moreover, while the foregoing discussion has been directed to solar cells having contacts on opposing sides, these techniques may be employed on any solar cell, including those with all contacts contained on a common side. The scope of the invention should be determined with respect to the appended claims, including the full scope of equivalents thereof.

1. A method of fabricating a solar cell having a p-n junction formed from introduction of an impurity element of a first conductivity type into a semiconductor substrate and formation of a layer of material of a second conductivity type, opposite to said first conductivity type and heating said substrate to anneal said substrate and growing, following said anneal, a layer of combined antireflective and protective material in superimposition with said p-n junction.

2. The method as recited in claim 1 wherein growing further includes exposing said substrate to plasma deposition chemistries.

3. The method as recited in claim 1 wherein said substrate is formed from silicon and growing further includes exposing said substrate to plasma deposition chemistries to form a layer of materials upon said substrate selected from a set of materials consisting essentially of aluminum oxide and silicon nitride.

4. The method as recited in claim 1 wherein heating further includes raising said substrate to a temperature proximate to a temperature sufficient to form said layer by exposing said substrate to plasma deposition chemistries.

5. The method as recited in claim 1 wherein heating further includes raising said substrate to a temperature proximate to a temperature sufficient to form said layer by exposing said substrate to plasma chemistries and maintaining said substrate proximate to said temperature white moving said substrate between adjacent processing stations of a semiconductor processing system.

6. The method as recited in claim 1 further including forming metal contacts, a first subset in electrical communication with a p-side of said p-n junction and a second subset in electrical communication with an n-side of said p-n junction.

7. A method of fabricating a solar cell comprising: disposing into a thermal processing apparatus a semiconductor substrate of a first conductivity type having a p-n junction formed therein by the presence of ions of a second conductivity type implanted therein;
applying heat to anneal said substrate with said thermal processing apparatus;
transferring said substrate from said thermal processing apparatus to a plasma deposition chamber while maintaining said temperature to be within a range of temperatures; and
forming a layer of combined antireflective and protective material in superimposition with said p-n junction by exposing said semiconductor substrate to plasma chemistries.

8. The method as recited in claim 7 further including applying metal contacts, a first subset being in electrical communication with a p-side of said p-n junction and a second subset being in electrical communication with an n-side of said p-n junction by exposing said substrate to an additional set of plasma chemistries.

9. The method as recited in claim 7 wherein said substrate is formed from silicon and forming further includes exposing said substrate of plasma deposition chemistries to form a layer of materials upon said substrate selected from a set of materials consisting essentially of aluminum oxide and silicon nitride.

10. The method as recited in claim 7 wherein heating further includes raising said substrate to a temperature proximate to a temperature sufficient to form said layer by exposing said substrate to said plasma chemistries.

11. A system for fabricating solar cells on a semiconductive substrate of a first conductivity type having a p-n junction formed by introduction of ion impurities of a second conductivity type, said system comprising:
multiple processing stations, including a thermal processing apparatus and a plasma processing chamber;
a substrate transport device configured to move a substrate between said multiple process stations;
a gas delivery system in fluid communication with said processing chamber;
a heating system including a pedestal in said plasma processing chamber, said pedestal for holding a substrate, said pedestal being heated to a selected temperature;
a vacuum system in fluid communication with said plasma processing chamber;
a microwave source in fluid communication with said plasma processing chamber; and
a processor in data communication with said thermal processing apparatus, said substrate transport device, said gas delivery system, said vacuum system, said heating system and said microwave source;
a memory in data communication with said processor; and
a computer readable program disposed within said memory to cause said processor to regulate operation of said thermal processing apparatus, said substrate transport device, said gas delivery system, said heater, said vacuum system and said microwave source; said computer readable program including a first set of computer instructions adapted to control said substrate transport device to dispose said semiconductor substrate into said thermal processing apparatus;
a second set of instruction adapted to control said thermal processing apparatus to generate heat and anneal said substrate; a third set of computer instructions adapted to control said substrate transport device to transfer said substrate from said thermal processing apparatus to said plasma deposition chamber while maintaining said temperature of said substrate to be within a range of temperatures; and a fourth set of instructions adapted to control said plasma processing chamber, said gas delivery system said heating system, said vacuum system, and said microwave source to form a layer of combined antireflective and protective material in superimposition with said P-N junction by exposing said semiconductor substrate to plasma chemistries.

12. The system as recited in claim 11 wherein said fourth set of instructions are adapted to control said plasma processing chamber, said gas delivery system, said heating system, said vacuum system, and said microwave source to form said layer from materials upon said substrate selected from a set of materials consisting essentially of aluminum oxide and silicon nitride.

13. The system as recited in claim 11 wherein said second set of instructions is adapted to control said thermal processing apparatus to heat said substrate; a third set of computer instructions adapted to control said substrate transport device to transfer said substrate from said thermal processing apparatus to said plasma deposition chamber while maintaining said temperature of said substrate to be within a range of temperatures.

14. The system as recited in claim 11 wherein said thermal processing apparatus is a load lock mechanism having a carrier to support and heat said semiconductive substrate in excess of 200° C.

15. The system as recited in claim 11 wherein said thermal processing apparatus is a load lock mechanism having a carrier to support said semiconductive substrate and a heating mechanism to heat opposing sides of said semiconductive substrate in excess of 200° C.

16. The system of claim 11 further including a thermal dissipation station, with said substrate transport device configured to move a substrate between said thermal processing apparatus, said plasma deposition chamber and said thermal dissipation station.

17. The system of claim 16 wherein said thermal dissipation station further includes a thermal transfer fluid in thermal communication with said semiconductive substrate.

18. The system as recited in claim 16 wherein thermal transfer fluid is selected from a set of liquids consisting essentially of a gas and a liquid.

19. The system of claim 11 further including a thermal dissipation station, with said thermal processing apparatus, said plasma deposition chamber and said thermal dissipation station being configured in a linear, in-line configuration and said substrate transport device being configured to move a substrate along a linear path between said thermal processing apparatus, said plasma deposition chamber and said thermal dissipation station.

20. The system of claim 11 further including a thermal dissipation station, with said thermal processing apparatus, said plasma deposition chamber and said thermal dissipation station being configured in diamond configuration, with said substrate transport device configured to move a substrate along two linear paths, each of which forms an oblique angle with respect to the remaining linear path of said two linear paths.
